(19) United States
(12) Patent Application Publication
(10) Pub. No.: US 2019/0392903 A1
(43) Pub. Date: Dec. 26, 2019

(54) NON-VOLATILE MEMORY DEVICE, MICROCOMPUTER, AND ELECTRONIC DEVICE

(71) Applicant: SEIKO EPSON CORPORATION, Tokyo (JP)

(72) Inventors: Takeshi MIYAZAKI, Chino-shi (JP); Masaki SHODA, Chino-shi (JP); Takashi HASEGAWA, Shiojiri-shi (JP)

(73) Assignee: SEIKO EPSON CORPORATION, Tokyo (JP)

(21) Appl. No.: 16/447,191

(22) Filed: Jun. 20, 2019

(30) Foreign Application Priority Data
Jun. 21, 2018 (JP) 2018-117754

(51) Int. Cl. G11C 16/16; G11C 16/26; G11C 16/24; G11C 16/08; G11C 16/34; G11C 16/30; H01L 27/11563; H01L 27/11517; G11C 16/04

(52) U.S. Cl. CPC G11C 16/16; G11C 16/26; G11C 16/24; G11C 16/08; G11C 16/0466; G11C 16/30; H01L 27/11563; H01L 27/11517; G11C 16/3459

(57) ABSTRACT

A non-volatile memory device 10 includes a first memory cell array MA1 in which a plurality of non-volatile memory cells are arranged, a first driver circuit DRC1, a first read/write circuit RWC1 that writes and reads out data, a second memory cell array MA2 in which a plurality of non-volatile memory cells having the same structure as the memory cells of the first memory cell array are arranged, a second driver circuit DRC2, and a second read/write circuit RWC2 that writes and reads out data. The first driver circuit DRC1 performs an erase operation in units of bytes on the first memory cell array MA1, and the second driver circuit DRC2 performs an erase operation in units of blocks, a block being larger than a byte, on the second memory cell array MA2.

The present application is based on, and claims priority from JP Application Serial Number 2018-117754, filed Jun. 21, 2018, the disclosure of which is hereby incorporated by reference herein in its entirety.

### BACKGROUND

### 1. Technical Field

The present invention relates to a non-volatile memory device, a microcomputer, an electronic device, and the like.

### 2. Related Art

Heretofore, memories such as EEPROMs (Electrically Erasable Programmable Read Only Memories) and flash memories are known.

EEPROMs and flash memories are non-volatile memory devices capable of electrically writing and erasing data, and are used as a memory device for storing data that is required to be held even after the power supply of an electronic device in which the EEPROM or flash memory is mounted is turned off. Examples of a conventional technique of a flash memory include a technique disclosed in JP-A-2004-326864.

The guaranteed number of times of rewriting of an EEPROM is large and the EEPROM is capable of writing and reading out data in units of bytes, and thus there is the advantage that the EEPROM is easy to use, but there is the disadvantage that its circuit area is large. On the other hand, a flash memory has the advantage that its circuit area can be reduced, but have the disadvantage that the guaranteed number of times of rewriting is small, and it is necessary to perform an erase operation in units of blocks. Thus, usages of the EEPROM and flash memory are different so as to make the most of their advantages, but processes for manufacturing memory cells of the EEPROM and flash memory are different, and thus there is a problem in that it is necessary to add a large number of manufacturing process steps in order to provide the EEPROM and flash memory together. On the other hand, there is also a technique called EEPROM emulation in which a partial region of a flash memory is used as an EEPROM. The technique disclosed in JP-A-2011-243230 is a known technique of EEPROM emulation.

JP-A-2004-326864 and JP-A-2011-243230 are examples of the related art.

However, in order to realize the number of times of rewriting equivalent to that of an EEPROM through the above-mentioned EEPROM emulation, it is necessary to increase the number of memory cells. For example, in order to guarantee the number of times of rewriting of 100000 when the number of times of rewriting of a flash memory is 1000, the number of memory cells that is 100 times of that of the flash memory is necessary. Therefore, there is a problem in that the circuit area increases, which causes an increase in the cost.

### SUMMARY

An aspect of the present disclosure pertains to a non-volatile memory device including a first memory cell array in which a plurality of non-volatile memory cells capable of electrically writing and erasing data are arranged, a first driver circuit that drives a word line and a source line of the first memory cell array, a first read/write circuit that is connected to bit lines of the first memory cell array, and writes/reads out data to/from the first memory cell array, a second memory cell array in which a plurality of non-volatile memory cells capable of electrically writing and erasing data and having the same structure as the plurality of memory cells of the first memory cell array are arranged, a second driver circuit that drives a word line and a source line of the second memory cell array, and a second read/write circuit that is connected to bit lines of the second memory cell array, and writes/reads out data to/from the second memory cell array, and the first driver circuit performs an erase operation in units of bytes on the first memory cell array, and the second driver circuit performs an erase operation in units of blocks larger than the byte unit, on the second memory cell array.

### BRIEF DESCRIPTION OF THE DRAWINGS

The disclosure will be described with reference to the accompanying drawings, wherein like numbers reference like elements.

FIG. 1 shows a configuration example of a non-volatile memory device of an embodiment of the present disclosure.

FIG. 2 is an explanatory diagram of operations of the non-volatile memory device.

FIG. 3 shows a detailed configuration example of the non-volatile memory device.

FIG. 4 shows a detailed configuration example of the non-volatile memory device.

FIG. 5 shows a detailed configuration example of the non-volatile memory device.

FIG. 6 is an explanatory diagram of EEPROM emulation.

FIG. 7 is an explanatory diagram of operations of EEPROM emulation.

FIG. 8 is an explanatory diagram of operations of an embodiment of the present disclosure.

FIG. 9 is an explanatory diagram of a technique for storing error correction codes.

FIG. 10 is an explanatory diagram related to improvement in the number of times of rewriting by using error correction codes.

FIG. 11 shows an example of the circuit configuration when using error correction codes.

FIG. 12 shows an example of the overall circuit configuration of a non-volatile memory device of an embodiment of the present disclosure.

FIG. 13 is an explanatory diagram of readout determination when complementary cells are not used.

FIG. 14 is an explanatory diagram of readout determination when complementary cells are used.

FIG. 15 shows a configuration example of memory cells of an MONOS structure.

FIG. 16 shows a configuration example of a microcomputer of an embodiment of the present disclosure.

FIG. 17 shows a configuration example of an electronic device of an embodiment of the present disclosure.

### DESCRIPTION OF EXEMPLARY EMBODIMENTS

The following is a detailed description of preferred embodiments of the present disclosure. Note that the embodiments described below are not intended to unduly limit the content of the present disclosure recited in the claims, and all of the configurations described in the embodiments are not necessarily essential as solutions provided by the present disclosure.

### 1. Non-Volatile Memory Device

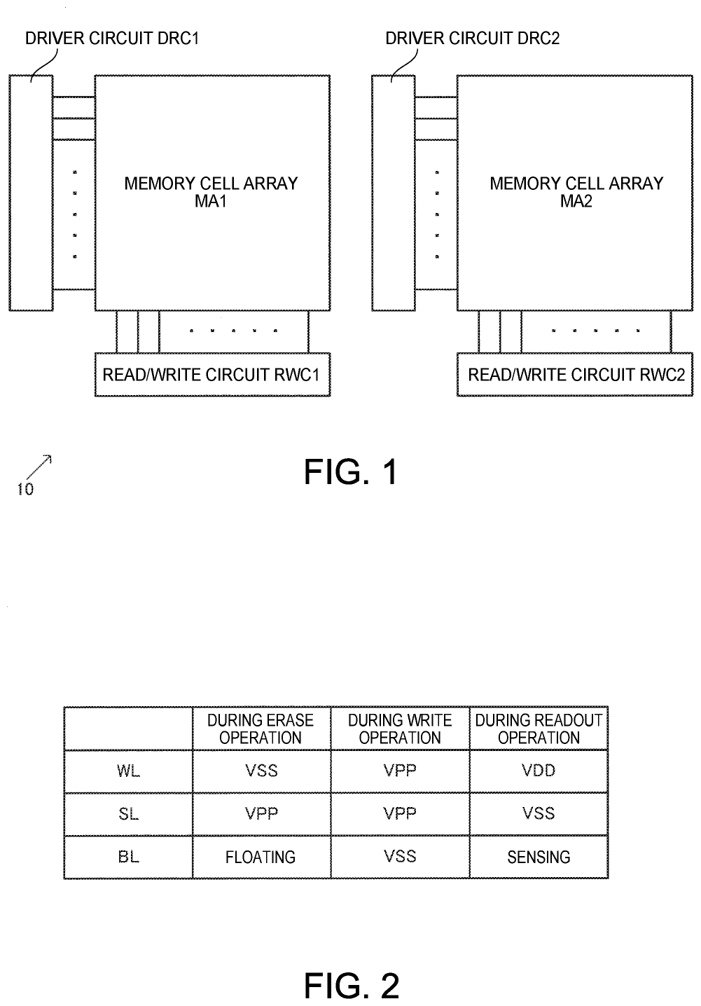

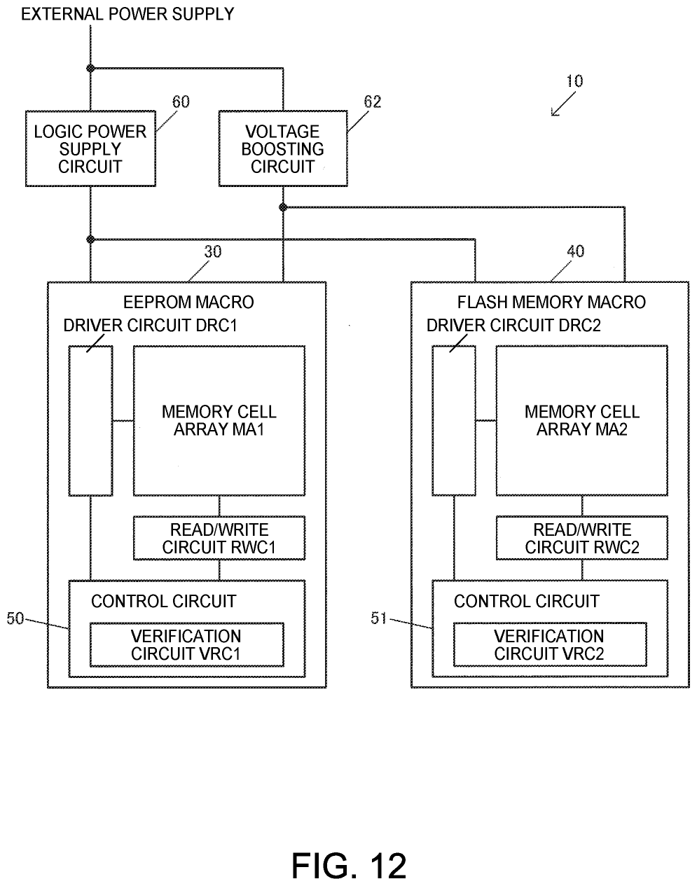

FIG. 1 shows a configuration example of a non-volatile memory device 10 of this embodiment. The non-volatile memory device 10, which is a circuit device, includes a memory cell array MA1, a driver circuit DRC1, and a read/write circuit RWC1, as well as a memory cell array MA2, a driver circuit DRC2, and a read/write circuit RWC2. The memory cell array MA1, the driver circuit DRC1, and the read/write circuit RWC1 constitute an EEPROM macro 30 as shown in FIG. 12 to be described later. The memory cell array MA2, the driver circuit DRC2, and the read/write circuit RWC2 constitute a flash memory macro 40.

A plurality of non-volatile memory cells capable of electrically writing and erasing data are arranged in the memory cell array MA1 that is a first memory cell array. Word lines, bit lines, and source lines that are connected to the memory cells are also provided in the memory cell array MA1.

The driver circuit DRC1 that is a first driver circuit drives the word lines and source lines of the memory cell array MA1. For example, the driver circuit DRC1 performs driving for outputting a word line voltage to a word line so as to select the word line, performs driving for outputting a source line voltage, which is a high voltage, to a source line, and performs an erase operation.

The read/write circuit RWC1 that is a first read/write circuit is connected to the bit lines of the memory cell array MA1, and writes/reads out data to/from the memory cell array MA1. For example, the read/write circuit RWC1 performs an operation of writing data to memory cells of the memory cell array MA1 via bit lines. The read/write circuit RWC1 also performs an operation of reading out data from memory cells of the memory cell array MA1 via bit lines.

A plurality of non-volatile memory cells capable of electrically writing and erasing data are arranged in the memory cell array MA2 that is a second memory cell array. Specifically, a plurality of non-volatile memory cells having the same structure as the memory cells of the memory cell array MA1 are arranged in the memory cell array MA2. Word lines, bit lines, and source lines connected to the memory cells are also provided in the memory cell array MA2. The non-volatile memory cells are memory cells that do not require power supply for holding data stored therein. The memory cells of the same structure are memory cells that have the same layer structure, for example, and readout, writing, and erase operations are respectively the same as those in the memory cells having the same structure. The memory cells of the same structure are memory cells that are formed in the same semiconductor manufacturing process, for example. Note that connection between circuits, connection between circuit elements, connection between a signal line and a circuit, and connection between a signal line and a circuit element in this embodiment are electrical connection. The electrical connection is connection that enables transmission of electrical signals, and connection that enables information transmission using electrical signals, and may be connection that is performed via a signal line, an active element, and the like.

The driver circuit DRC2 that is a second driver circuit drives the word lines and the source lines of the memory cell array MA2. For example, the driver circuit DRC2 performs driving for outputting a word line voltage to a word line so as to select the word line, performs driving for outputting a source line voltage, which is a high voltage, to a source line, and performs an erase operation.

The read/write circuit RWC2 that is a second read/write circuit is connected to the bit lines of the memory cell array MA2, and writes/reads out data to/from the memory cell array MA2. For example, the read/write circuit RWC2 performs an operation of writing data to memory cells of the memory cell array MA2 via bit lines. Also, the read/write circuit RWC2 performs an operation of reading out data from memory cells of the memory cell array MA2 via bit lines.

In addition, in this embodiment, the driver circuit DRC1 performs an erase operation in units of bytes on the memory cell array MA1. For example, the driver circuit DRC1 performs an erase operation in units of eight bits. On the other hand, the driver circuit DRC2 performs an erase operation in units of blocks on the memory cell array MA2. For example, the driver circuit DRC2 performs an erase operation in units of blocks, a block being larger than a byte. The block unit is a multibyte unit, for example.

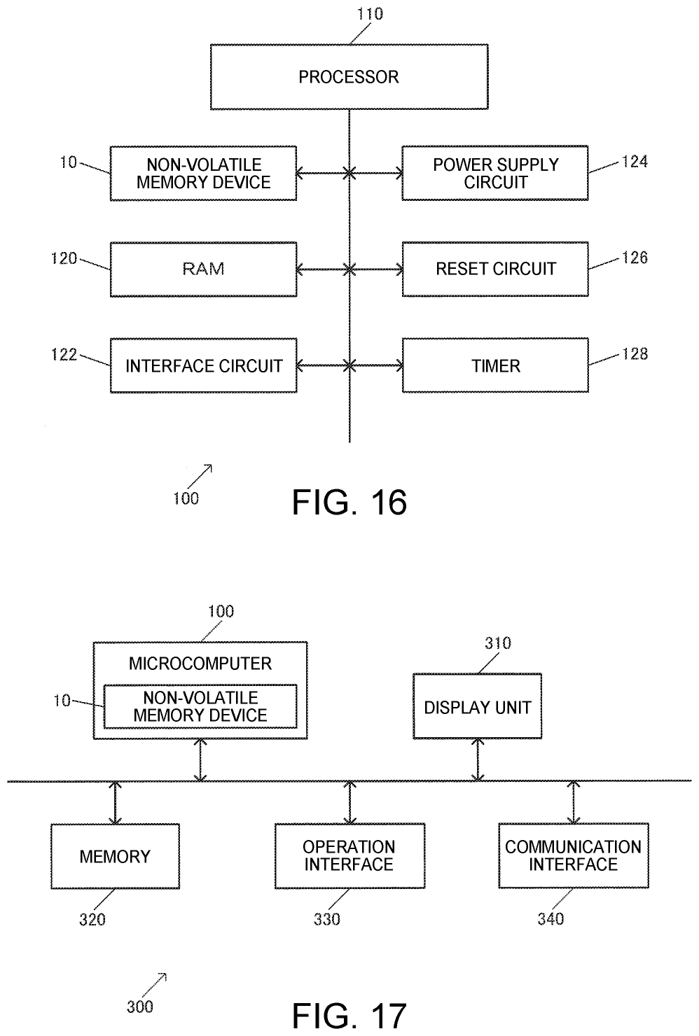

As described above, in this embodiment, an erase operation in units of bytes is performed in the memory cell array MA1 as with the case of an EEPROM, and an erase operation in units of blocks is performed in the memory cell array MA2 as with the case of a flash memory. Therefore, the memory cell array MA1 can be handled as an EEPROM, and the memory cell array MA2 can be handled as a flash memory. As a result, it is possible to realize the non-volatile memory device 10 equipped with both an EEPROM and a flash memory, using memory cells of the same structure, and it is possible to cope with both an usage of the EEPROM and an usage of the flash memory. For example, in a microcomputer 100 in FIG. 16 to be described later, an EEPROM is used for storing user data and a flash memory is used for storing a firmware program. In this case, according to this embodiment, only by providing one non-volatile memory device 10 in the microcomputer 100, the memory cell array MA1 stores the user data, and the memory cell array MA2 stores the firmware program, making it possible to cope with the above-described usages. In addition, memory cells of the same structure are used for the memory cell arrays MA1 and MA2, and thus it is possible to form memory cells of the memory cell arrays MA1 and MA2 using the same process for manufacturing a semiconductor. Therefore, a new manufacturing process step does not need to be added, and the cost can be reduced. In addition, by realizing the memory cell arrays MA1 and MA2 with memory cells of an MONOS (Metal Oxide Nitride Oxide Silicon) structure or the like, it is possible to reduce the circuit area, and achieve further reduction in the cost. In addition, EEPROM emulation processing is not required, and thus it is not necessary to load a program for this emulation processing to a RAM 120 in FIG. 16, for example. Therefore, it is possible to prevent the available storage capacity of the RAM 120 from being reduced due to the program for the EEPROM emulation processing.

In addition, in this embodiment, during an erase operation in units of bytes, the driver circuit DRC1 supplies an erasure voltage to a source line of a memory cell group connected to a bit line group corresponding to the byte unit. For example, a high erasure voltage is supplied to a source line connected in common in a memory cell group that stores one-byte data. At this time, for example, VSS, which is a low voltage, is supplied to the word line of the memory cell group. With such a configuration, an erase operation in units of bytes can be performed on the memory cell array MA1. On the other hand, during an erase operation in units of blocks, the driver circuit DRC2 supplies an erasure voltage to a source line of a memory cell group connected to a bit line group corresponding to the block unit. Accordingly, the driver circuit DRC2 supplies, to the source line, an erasure voltage same as the erasure voltage that is supplied by the driver circuit DRC1. For example, an erasure voltage is supplied to a source line connected in common in a memory cell group that stores data in units of blocks, and VSS, which is a low voltage, is supplied to the word line. With such a configuration, a batch erase operation in units of blocks can be performed in the memory cell array MA2.

In addition, the memory cell array MA1 includes a first memory cell group that stores one-byte first data and a second memory cell group that stores one-byte second data. Each of the first and second memory cell groups has eight or more memory cells corresponding to one byte, for example. For example, if complementary data is stored as bit data in each bit of 8 bits, each memory cell group has 16 or more memory cells. In addition, as will be described later, if each memory cell group stores an error correction code, the memory cell group is further provided with a number of memory cells for storing data of the respective bits of the error correction code.

The driver circuit DRC1 performs an erase operation in units of bytes on the first memory cell group, and, after the erase operation, the read/write circuit RWC1 writes first data to the first memory cell group. Also, the driver circuit DRC1 performs an erase operation in units of bytes on the second memory cell group, and, after the erase operation, the read/write circuit RWC1 writes second data to the second memory cell group. With such a configuration, after the erase operation in units of bytes on the first memory cell group, the first data that is one-byte data can be written to the first memory cell group. Also, after the erase operation in units of bytes on the second memory cell group, the second data that is one-byte data can be written to the second memory cell group. Therefore, processing for writing data in units of bytes is possible as with the case of an EEPROM, and the memory cell array MA1 can be used for the usage of the EEPROM.

FIG. 2 is an explanatory diagram of operations of the non-volatile memory device 10. As shown in FIG. 2, during an erase operation, a word line WL is set to VSS, a source line SL is set to VPP, and bit lines BL are set to a floating state. VSS is 0 V, for example. However, VSS may be a negative voltage. VPP is a high voltage, and is 7.5 V, for example, and is an erasing and rewriting voltage. During a write operation, a word line WL is set to VPP, a source line SL is set to VPP, and bit lines BL are set to VSS. During a readout operation, a word line WL is set to VDD, a source line SL is set to VSS, the potentials of bit lines BL are sensed by sense amplifiers of the read/write circuits RWC1 and RWC2, and data is read out. VDD is a voltage lower than VPP, and is 1.8 V, for example. In an erase operation, positive charges are injected into a charge accumulation layer of a memory cell, and thereby “1” is stored in the memory cell. Also, in a write operation, negative charges are injected into a charge accumulation layer of a memory cell, and thereby data stored in the memory cell is rewritten from “1” to “0”.

### 2. Detailed Configuration Example

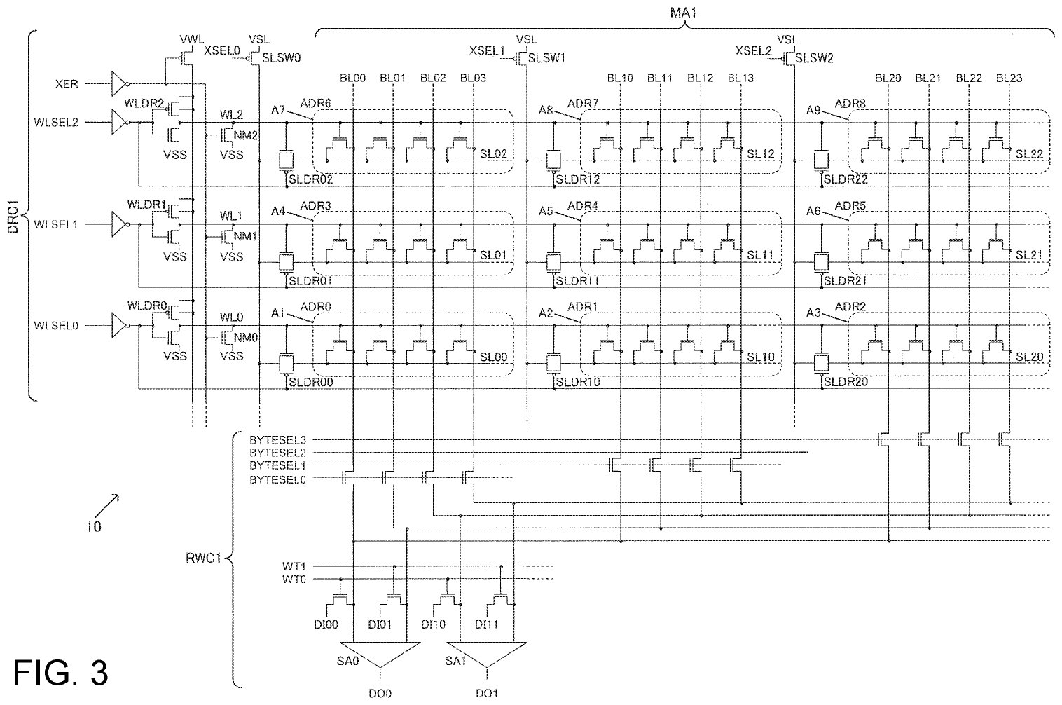

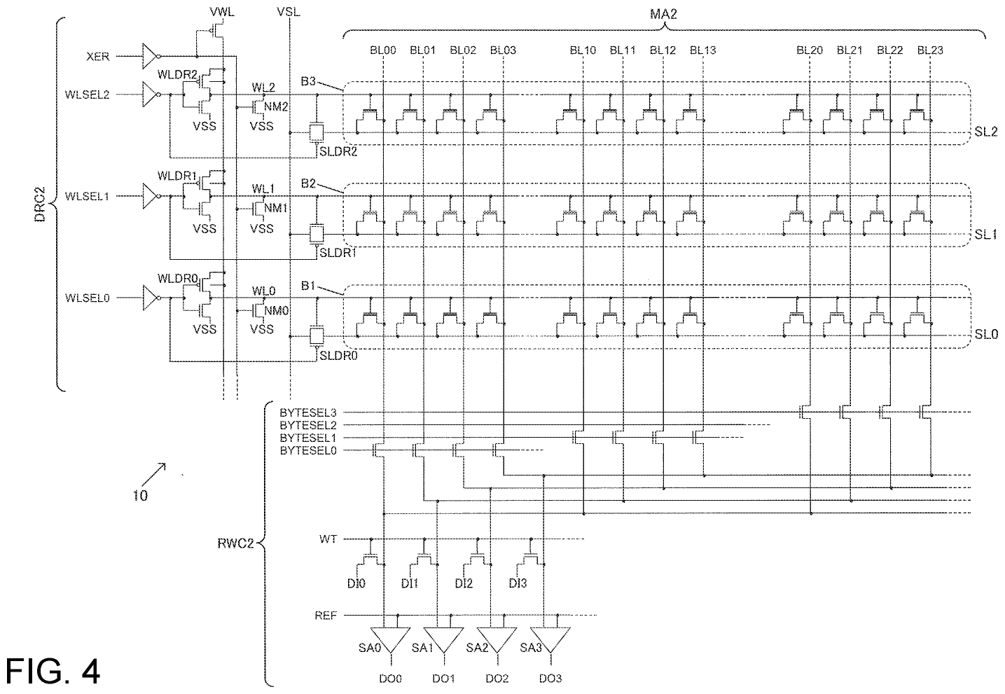

FIGS. 3 and 4 show detailed configuration examples of the non-volatile memory device 10 of this embodiment. FIG. 3 is a diagram showing a detailed configuration example of the memory cell array MA1, the driver circuit DRC1, and the read/write circuit RWC1.

The memory cell array MA1 includes a plurality of memory cells as indicated by A1 to A9. A1 to A9 denotes memory cell groups that are designated by addresses ADR0 to ADR8. Note that a number of memory cells corresponding to one byte are actually provided in each of the memory cell groups A1 to A9, but illustration thereof is omitted to simplify the description. In this embodiment, as will be described later, data of each bit is stored as complementary data having a mutually complementary relationship, and thus, for example, 16 memory cells corresponding to one byte are provided in each of the memory cell groups A1 to A9. Note that, when storing an error correction code, memory cells for storing the error correction code is further added. For example, if the number of bits of an error correction code is four, and when the error correction code is stored as complementary data as well, the number of memory cells that are provided in each memory cell group is 24.

The driver circuit DRC1 includes word line drivers WLDR0 to WLDR2 for driving the word lines, pull-down switch elements NM0 to NM2, switch elements SLSW0 to SLSW2 for selecting a source line voltage, and switch elements SLDR00 to SLDR22 for driving the source lines. The switch elements NM0 to NM2 are realized by N-type transistors. The switch elements SLSW0 to SLSW2 are realized by P-type transistors. The switch elements SLDR00 to SLDR22 are realized by transfer gates. The N-type and P-type transistors are MOS (Metal Oxide Semiconductor) transistors. A transfer gate is a switch element constituted by an N-type transistor and a P-type transistor.

The read/write circuit RWC1 includes sense amplifiers SA0 and SA1, switch elements for byte selection, and switch elements for data input. These switch elements are realized by N-type transistors.

Next, an erase operation, a write operation, and a readout operation in FIG. 3 will be described individually in detail. In FIG. 3, VWL denotes a word line voltage that changes to VPP, which is a high voltage, when writing data, and changes to VDD, which is a logic voltage, when reading out data. VSL denotes a source line voltage that changes to VPP, which is a high voltage, when erasing data, and changes to VSS, which is a ground potential, when reading out data. VSS corresponds to an L level that is a level of logic “0”. XER denotes an erase signal, which is a negative logic signal that changes to L level when erasing data, and changes to an H level that is a level of logic “1” otherwise.

WT0 and WT1 denote write signals, and when writing data, one of WT0 and WT1 changes to H level. When reading out data, both WT0 and WT1 change to H level, and, when erasing data, both WT0 and WT1 change to L level. WLSEL0 to WLSEL2 denote word line select signals, which change to H level for a selected word line, and change to L level for non-selected word lines.

XSEL0 to XSEL2 denote source line select signals, which are negative logic signals that change to L level for a selected source line, and change to H level for non-selected source lines. BYTESEL0 to BYTESEL3 denote byte select signals, which change to H level for a selected byte, and change to L level for non-selected bytes. DI00, DI01, DI10, and DI11 denote input data signals, and DO0 and DO1 denote output data signal. WL0 to WL2 denote word lines, SL00 to SL22 denotes source lines, and BL00 to BL23 denote bit lines.

During an erase operation, the erase signal XER changes to L level, the word line voltage VWL that is a power supply voltage is no longer supplied to the word line drivers WLDR0 to WLDR2, the switch elements NM0 to NM2 are switched on, and VSS is applied to the word lines WL0 to WL2. The byte select signals BYTESEL0 to BYTESEL3 then change to L level, and thereby all of the bit lines BL00 to BL23 enter a high impedance state. In addition, one of the source line select signals XSEL0 to XSEL2 changes to L level, a corresponding switch element from among the switch elements SLSW0 to SLSW2 is switched on, and the source line voltage VSL (=VPP) is supplied to the other end of this switch element. In addition, as a result of one of the word line select signals WLSEL0 to WLSEL2 changing to H level, a corresponding switch element from among the switch elements SLDR00 to SLDR22 is switched on. Accordingly, the source line voltage VSL (=VPP) is applied to a corresponding source line from among the source lines SL00 to SL22.

For example, when the word line select signal WLSEL0 changes to H level and the switch element SLDR00 is switched on, and the source line select signal XSEL0 changes to L level and the switch element SLSW0 is switched on, the source line voltage VSL (=VPP) is applied to the source line SL00 that is connected to the memory cell group indicated by A1 in FIG. 3. Accordingly, the memory cell group indicated by A1 is set as an erase target, and an erase operation in units of bytes is performed. In addition, when the word line select signal WLSEL0 changes to H level and the switch element SLDR10 is switched on, and the source line select signal XSEL1 changes to L level and the switch element SLSW1 is switched on, the source line voltage VSL (=VPP) is applied to the source line SL10 that is connected to the memory cell group indicated by A2. Accordingly, the memory cell group indicated by A2 is set as an erase target, and an erase operation in units of bytes is performed. In addition, when the word line select signal WLSEL1 changes to H level and the switch element SLDR01 is switched on, and the source line select signal XSEL0 changes to L level and the switch element SLSW0 is switched on, the source line voltage VSL (=VPP) is applied to the source line SL01 that is connected to the memory cell group indicated by A4. Accordingly, the memory cell group indicated by A4 is set as an erase target, and an erase operation in units of bytes is performed.

As described above, in this embodiment, an erase operation can be performed on the memory cell groups that are set in units of bytes and indicated by A1 to A9, and an erase operation in units of bytes can be executed. Specifically, it is possible to perform an erase operation on the memory cell groups A1 to A9 respectively designated by the addresses ADR0 to ADR8. In addition, in this embodiment, when rewriting data, an erase operation is performed only on a memory cell group that is a data rewrite target. For example, when writing one-byte data to the memory cell group that is indicated by A1 and designated by the address ADR0, an erase operation is performed only on the memory cell group indicated by A1. Also, when writing one-byte data to the memory cell group that is indicated by A2 and designated by the address ADR1, an erase operation is performed only on the memory cell group indicated by A2.

During a write operation, one of the byte select signals BYTESEL0 to BYTESEL3 changes to H level, one of the write signals WT1 and WT0 changes to H level, and the input data signals DI00 to DI11 change to voltage levels corresponding to input data. Accordingly, voltages are applied to selected bit lines. In addition, during the write operation, as a result of the erase signal XER changing to H level, the word line voltage VWL (=VPP), which is a power supply voltage, is supplied to the word line drivers WLDR0 to WLDR2. One of the word line select signals WLSEL0 to WLSEL2 then changes to H level, a corresponding word line driver from among the word line drivers WLDR0 to WLDR2 outputs VWL (=VPP), and a corresponding switch element from among the switch elements SLDR00 to SLDR22 is switched on. Accordingly, the word line voltage VWL (=VPP) and the source line voltage VSL (=VPP) are applied to a corresponding word line and a corresponding source line, and data is written to a selected memory cell group.

For example, when writing data to the memory cell group indicated by A1, the byte select signal BYTESEL0 changes to H level, and the word line voltage VWL (=VPP) and the source line voltage VSL (=VPP) are applied to the word line WL0 and the source line SL00. Accordingly, one-byte data can be written to the memory cell group indicated by A1. In addition, when writing data to the memory cell group indicated by A2, the byte select signal BYTESEL1 changes to H level, and the word line voltage VWL (=VPP) and the source line voltage VSL (=VPP) are applied to the word line WL0 and the source line SL10. Accordingly, one-byte data can be written to the memory cell group indicated by A2. In addition, when writing data to the memory cell group indicated by A4, the byte select signal BYTESEL0 changes to H level, and the word line voltage VWL (=VPP) and the source line voltage VSL (=VPP) are applied to the word line WL1 and the source line SL01. Accordingly, one-byte data can be written to the memory cell group indicated by A4.

Also, in this embodiment, when rewriting data, rewriting is performed only for a target byte. For example, if data stored in the memory cell group A1 corresponds to the byte targeted for data rewriting, an erase operation is performed on the memory cell group A1, and data is written to the memory cell group A1. If data stored in the memory cell group A2 corresponds to the byte targeted for data rewriting, an erase operation is performed on the memory cell group A2, and data is written to the memory cell group A2.

Note that, in this embodiment, two memory cells provided for each bit store complementary data having a mutually complementary relationship as the data of the bit. For example, a first memory cell corresponding to the input data signal DI00 stores first bit data, and a second memory cell corresponding to the input data signal DI01 stores second bit data that is complementary to the first bit data. For example, if a first logic level “0” is stored in the first and second memory cells, the first memory cell stores “0” as the first bit data, and the second memory cell stores “1” as the second bit data. If a second logic level “1” is stored in the first and second memory cells, the first memory cell stores “1” as the first bit data, and the second memory cell stores “0” as the second bit data.

For example, due to an erase operation, the first and second memory cells enter a state of storing “1”. When writing “0” as bit data after the erase operation, “0” is written to the first memory cell. In this case, the write signal WT0 changes to H level, and the write signal WT1 changes to L level. As a result of the input data signal DI00 changing to VSS, the bit line BL00 is set to VSS, and, in the first memory cell, as a result of a current flowing from its source line to the bit line BL00, “0” is written to the first memory cell. On the other hand, when writing “1” as bit data, “0” is written to the second memory cell. In this case, the write signal WT0 changes to L level, and the write signal WT1 changes to H level. Then, as a result of the input data signal DI01 changing to VSS, the bit line BL01 is set to VSS, and, in the second memory cell, as a result of a current flowing from its source line to the bit line BL01, “0” is written to the second memory cell.

During a readout operation, one of the byte select signals BYTESEL0 to BYTESEL3 changes to H level, and selected bit lines and the sense amplifiers SA0 and SA1 are connected. Also, during the readout operation, as a result of the erase signal XER changing to H level, the word line voltage VWL (=VDD) that is a power supply voltage is supplied to the word line drivers WLDR0 to WLDR2. Also, during the readout operation, the source line voltage is set to VSL (=VSS). One of the word line select signals WLSEL0 to WLSEL2 then changes to H level, and a corresponding word line driver from among the word line drivers WLDR0 to WLDR2 outputs VWL (=VDD), and a corresponding switch element from among the switch elements SLDR00 to SLDR22 is switched on. Accordingly, the word line voltage VWL (=VDD) and the source line voltage VSL (=VSS) are applied to a corresponding word line and a corresponding source line, and data is read out from the selected memory cell group. Specifically, detection currents flowing in adjacent memory cells of a memory cell group are compared using the sense amplifiers SA0 and SA1, and thereby data is read out.

For example, each of the sense amplifiers SA0 and SA1 has a current mirror circuit. Also, the sense amplifier SA0 reads out data from the first and second memory cells that store complementary data, by comparing a first detection current that flows from the current mirror circuit to the first memory cell with a second detection current that flows from the current mirror circuit to the second memory cell. The sense amplifier SA1 reads out data from the third and fourth memory cells that store complementary data, by comparing a third detection current that flows from the current mirror circuit to the third memory cell with a fourth detection current that flows from the current mirror circuit to the fourth memory cell.

Here, the first and second memory cells are adjacent memory cells, and the third and fourth memory cells are adjacent memory cells. In addition, in this embodiment, when “1” is stored in a memory cell, a detection current that is a current flowing in the memory cell is larger compared with a case where “0” is stored. Therefore, when the first memory cell stores “1” and the second memory cell stores “0” that is in a complementary relationship with “1”, the first detection current that flows in the first memory cell is larger than the second detection current that flows in the second memory cell. Therefore, in this case, the sense amplifier SA0 outputs the output data signal DO0 of H level corresponding to the logic “1”. In addition, when the first memory cell stores “0”, and the second memory cell stores “1” that is in a complementary relationship with “0”, the second detection current is larger than the first detection current. Therefore, in this case, the sense amplifier SA0 outputs the output data signal DO0 of L level corresponding to the logic “0”. This applies to operations of the third and fourth memory cells and the sense amplifier SA1.

FIG. 4 is a diagram showing a detailed configuration example of the memory cell array MA2, the driver circuit DRC2, and the read/write circuit RWC2. Note that detailed description on portions in FIG. 4 that are similar to FIG. 3 is omitted.

The switch elements SLSW0, SLSW1, and SLSW2 as well as the switch elements SLDR10, SLDR20, SLDR11, SLDR21, SLDR12, and SLDR22 provided in the driver circuit DRC1 in FIG. 3 are not provided in the driver circuit DRC2 in FIG. 4. The source line voltage VSL is supplied to source lines SL0, SL1, and SL2 via switch elements SLDR0, SLDR1, and SLDR2 respectively. Specifically, in FIG. 3, a plurality of memory cells of the memory cell array MA1 are divided into memory cell groups that are set in units of bytes and are indicated by A1 to A9, using the switch elements SLSW0 to SLSW2 and the switch elements SLDR00 to SLDR22. Moreover, the source lines SL00 to SL22 are connected in common in the memory cell groups that are set in units of bytes and indicated by A1 to A9, respectively. On the other hand, in FIG. 4, the memory cells are not divided into memory cell groups in units of bytes in this manner. The source line SL0 is connected in common in a memory cell group that is set in units of blocks and is indicated by B1, the source line SL1 is connected in common in a memory cell group that is set in units of blocks and is indicated by B2, and the source line SL2 is connected in common in a memory cell group that is set in units of blocks and is indicated by B3.

In addition, in FIG. 3, a configuration is adopted in which complementary data is stored as each piece of bit data, but, in FIG. 4, such a configuration in which complementary data is stored is not adopted. Therefore, the configuration of the read/write circuit RWC2 in FIG. 4 is also different from the configuration of the read/write circuit RWC1 in FIG. 3. For example, in FIG. 3, two write signals, namely the write signals WT0 and WT1 are provided, but, in FIG. 4, only one write signal, namely a write signal WT is provided. The input data signals DI0 to DI3 are input via switch elements that are switched on/off by the write signal WT. In addition, sense amplifiers SA0 to SA3 in FIG. 4 are configured to compare a reference current REF with detection currents from bit lines, and to output data signals DO0 to DO3. Note that modification can also be made in the memory cell array MA2 in FIG. 4 so as to adopt the complementary cell configuration. In this case, the configuration in FIG. 3 may be used.

Next, an erase operation, a write operation, and a readout operation in FIG. 4 will be described briefly. During an erase operation, as a result of the erase signal XER changing to L level and the switch elements NM0 to NM2 being switched on, VSS is applied to the word lines WL0 to WL2. Then, as a result of the byte select signals BYTESEL0 to BYTESEL3 changing to L level, all of the bit lines BL00 to BL23 enter a high impedance state. In addition, one of the word line select signals WLSEL0 to WLSEL2 changes to H level, and a corresponding switch element from among the switch elements SLDR0 to SLDR2 is switched on. Accordingly, the source line voltage VSL (=VPP) is applied to a corresponding source line from among the source lines SL0 to SL2. With such a configuration, an erase operation can be performed on memory cell groups that are set in units of blocks and are indicated by B1 to B3. For example, as a result of the word line select signal WLSEL0 changing to H level and the switch element SLDR0 being switched on, VSL (=VPP) is applied to the source line SL0, and an erase operation is performed on the memory cell group that is set in units of blocks and is indicated by B1. In addition, as a result of the word line select signal WLSEL1 changing to H level and the switch element SLDR1 being switched on, VSL (=VPP) is applied to the source line SL1, and an erase operation is performed on the memory cell group that is set in units of blocks and is indicated by B2. The same applies to an erase operation on the memory cell group B3.

During a write operation, one of the byte select signals BYTESEL0 to BYTESEL3 changes to H level, the write signal WT changes to H level, and the input data signals DI0 to DI3 change to voltage levels corresponding to input data. Accordingly, voltages are applied to selected bit lines. In addition, one of the word line select signals WLSEL0 to WLSEL2 changes to H level, a corresponding word line driver from among the word line drivers WLDR0 to WLDR2 outputs VWL (=VPP), and a corresponding switch element from among the switch elements SLDR0 to SLDR2 is switched on. Accordingly, the word line voltage VWL (=VPP) and the source line voltage VSL (=VPP) are applied to a corresponding word line and a corresponding source line, and data is written to a selected memory cell group in units of bytes.

During a readout operation, one of the byte select signals BYTESEL0 to BYTESEL3 changes to H level, and selected bit lines and the sense amplifiers SA0 to SA3 are connected. One of the word line select signals WLSEL0 to WLSEL2 then changes to H level, a corresponding word line driver from among the word line drivers WLDR0 to WLDR2 outputs VWL (=VDD), and a corresponding switch element from among the switch elements SLDR0 to SLDR2 is switched on. Accordingly, the word line voltage VWL (=VDD) and the source line voltage VSL (=VSS) are applied to a corresponding word line and a corresponding source line, and data is read out from a selected memory cell group that is set in units of bytes. Specifically, the sense amplifiers SA0 to SA3 compare the reference current REF with detection currents that flow in the memory cells of the selected memory cell group, and output the output data signals DO0 to D03.

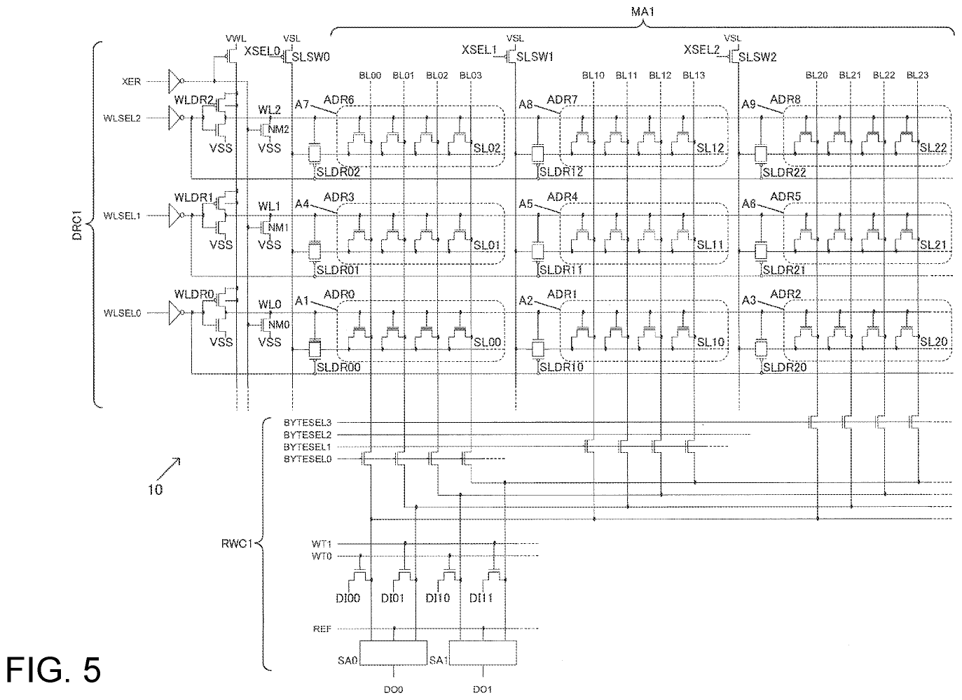

FIG. 5 shows another configuration example of the non-volatile memory device 10 in detail. The configuration of the read/write circuit RWC1 in FIG. 5 is different from that in FIG. 3. Specifically, the configuration of the sense amplifiers SA0 and SA1 is different, and operations in a dual mode and a single mode are possible. In the dual mode, similarly to FIG. 3, the memory cell array MA1 stores complementary data as each bit data. A readout operation in the dual mode is an operation similar to that in FIG. 3. Specifically, by the sense amplifiers SA0 and SA1 comparing detection currents that flow in adjacent memory cells of a memory cell group, data is read out. On the other hand, in a readout operation in the single mode, by the sense amplifiers SA0 and SA1 comparing a detection current that flows in one of adjacent memory cells with a reference current, data is read out.

Specifically, in the dual mode, the first memory cell and the second memory cell of a memory cell group store mutually complementary data, and, in the single mode, store separate pieces of data. In addition, in the dual mode, the read/write circuit RWC1 reads out complementary data stored in the first and second memory cells by comparing the first detection current that flows in the first memory cell and the second detection current that flows in the second memory cell. On the other hand, in the single mode, the read/write circuit RWC1 reads out data stored in the first memory cell by comparing the first detection current that flows in the first memory cell with the reference current REF, and reads out data stored in the second memory cell by comparing the second detection current that flows in the second memory cell with the reference current REF. With such a configuration, the guaranteed number of times of rewriting is large, and it is possible to cope with a usage for which a high endurance property is required, by setting the non-volatile memory device 10 to the dual mode that is a first mode. On the other hand, it is possible to cope with a usage for which a large storage capacity is required more than the endurance property, by setting the non-volatile memory device 10 to the single mode that is a second mode.

As described above, the non-volatile memory device 10 of this embodiment includes the memory cell array MA1 in which memory cells are arranged, the driver circuit DRC1 that drives the word lines and the source lines, and the read/write circuit RWC1 that writes/reads out data to/from the memory cell array MA1. In addition, the non-volatile memory device 10 includes the memory cell array MA2 in which memory cells having the same structure as the memory cells of the memory cell array MA1 are arranged, the driver circuit DRC2 that drives the word lines and the source lines, and the read/write circuit RWC2 that writes/reads out data to/from the memory cell array MA2.

The driver circuit DRC1 performs an erase operation in units of bytes on the memory cell array MA1. In other words, an erase operation is performed on the memory cell groups that are set in units of bytes as indicated by A1 to A9 in FIG. 3. On the other hand, the driver circuit DRC2 performs an erase operation in units of blocks on the memory cell array MA2. In other words, an erase operation is performed on the memory cell groups that are set in units of blocks, a block being larger than a byte in A1 to A9 in FIG. 3, as indicated by B1 to B3 in FIG. 4.

As described above, in this embodiment, a batch erase operation in units of blocks is performed on the memory cell array MA2 as with the case of a flash memory, while an erase operation in units of bytes is performed on the memory cell array MA1 as with the case of an EEPROM. For example, when designating an address and writing data, an erase operation is performed on a memory cell group designated by this address, and, after the erase operation, one-byte data is written to this memory cell group. For example, in FIG. 3, when writing one-byte data to the address ADR0, the driver circuit DRC1 performs an erase operation on the memory cell group A1 corresponding to the address ADR0. Subsequently after the erase operation, the read/write circuit RWC1 writes the one-byte data to the memory cell group A1.

In addition, when writing one-byte data to the address ADR1, the driver circuit DRC1 performs an erase operation on the memory cell group A2 corresponding to the address ADR1. Subsequently after the erase operation, the read/write circuit RWC1 writes the one-byte data to the memory cell group A2. The same applies to erase operations and write operations on the memory cell groups A3 to A9 corresponding to the addresses ADR2 to ADR8. Note that, before the erase operation, a write operation (before erasing) in units of bytes for uniformizing the threshold values of memory cells is performed. In addition, when reading out data, one-byte data is read out from the memory cell groups A1 to A9 designated respectively by the addresses ADR0 to ADR8. On the other hand, a batch erase operation is performed on the memory cell array MA2 in FIG. 4 similarly to a normal flash memory, and data is written/read out. With such a configuration, both a usage of an EEPROM and a usage of a flash memory can be coped with using one non-volatile memory device 10. For example, the non-volatile memory device 10 can be used such that user data and the like are written and stored in the memory cell array MA1, and a firmware program and the like are written and stored in the memory cell array MA2. In addition, the memory cells of the memory cell array MA1 and the memory cells of the memory cell array MA2 are memory cells of the same structure, and it is possible to use memory cells of a MONOS structure or the like that are usually used in a flash memory. Therefore, even if the storage capacity of the memory cell array MA1 is increased to increase the storage capacity that is used for user data, it is possible to suppress an increase in the circuit area to a minimum.

In addition, in this embodiment, during an erase operation in units of bytes, the driver circuit DRC1 supplies an erasure voltage to a source line of a memory cell group connected to a bit line group corresponding to the byte unit. Regarding the memory cell group A1 in FIG. 3 as an example, during an erase operation, the driver circuit DRC1 supplies the source line voltage VSL (=VPP), which is an erasure voltage, to the source line SL00 of the memory cell group A1 connected to the bit lines BL00, BL01, BL02, BL03, and the like constituting a bit line group corresponding to the byte unit. Regarding the memory cell group A2 as an example, during an erase operation, the driver circuit DRC1 supplies the source line voltage VSL (=VPP), which is an erasure voltage, to the source line SL10 of the memory cell group A2 connected to the bit lines BL01, BL11, BL12, BL13, and the like constituting a bit line group corresponding to the byte unit. With such a configuration, an erase operation in units of bytes can be performed on the memory cell array MA1.

On the other hand, during an erase operation in units of blocks, the driver circuit DRC2 supplies an erasure voltage to a source line of a memory cell group connected to a bit line group corresponding to the block unit. Regarding the memory cell group B1 in FIG. 4 as an example, during an erase operation, the driver circuit DRC2 supplies the source line voltage VSL (=VPP), which is an erasure voltage, to the source line SL0 of the memory cell group B1 connected to the bit lines BL00 to BL23 and the like constituting a bit line group corresponding to the block unit. Regarding the memory cell group B2 as an example, during an erase operation, the driver circuit DRC2 supplies the source line voltage VSL (=VPP), which is an erasure voltage, to the source line SL1 of the memory cell group B2 connected to the bit lines BL00 to BL23 and the like constituting a bit line group corresponding to the block unit. With such a configuration, an erase operation in units of blocks can be performed on the memory cell array MA2.

In addition, in this embodiment, the memory cell array MA1 includes a first memory cell group that stores first data of one byte and a second memory cell group that stores second data of one byte. As an example, the memory cell group indicated by A1 in FIG. 3 is the first memory cell group, and the memory cell group indicated by A2 is the second memory cell group. Note that this embodiment is not limited thereto, and, for example, a configuration may be adopted in which A1 denotes the first memory cell group, and one of A3 to A9 denotes the second memory cell group.

The driver circuit DRC1 performs an erase operation in units of bytes on the first memory cell group, and, after the erase operation, the read/write circuit RWC1 writes the first data to the first memory cell group. For example, when the address ADR0 is designated, an erase operation is performed on the first memory cell group A1 corresponding to the address ADR0, and, after that, an operation of writing the first data of one byte is performed on the first memory cell group. In addition, the driver circuit DRC1 performs an erase operation in units of bytes on the second memory cell group, and, after the erase operation, the read/write circuit RWC1 writes the second data to the second memory cell group. For example, when the address ADR1 is designated, an erase operation is performed on the second memory cell group A2 corresponding to the address ADR1, and after that, an operation of writing the second data of one byte is performed on the second memory cell group. With such a configuration, an erase operation is performed only on a memory cell group that is a data writing target. Therefore, it is possible to prevent a situation in which an erase operation is performed in vain on a memory cell group that is not a data writing target, the endurance property deteriorates, and the like.

In addition, in this embodiment, the first memory cell group stores complementary data that is mutually complementary as the data of each bit of the first data, and the second memory cell group stores complementary data that is mutually complementary as the data of each bit of the second data. For example, a first memory cell of the first memory cell group stores first bit data, and a second memory cell of the first memory cell group stores second bit data that is complementary to the first bit data. For example, when the first memory cell stores “0”, the second memory cell stores “1”, and when the first memory cell stores “1”, the second memory cell stores “0”. Similarly, a first memory cell of the second memory cell group stores third bit data, and a second memory cell of the second memory cell group stores fourth bit data that is complementary to the third bit data. By storing each piece of bit data that is complementary to the other in this manner, the number of times of rewriting can be increased, and the endurance property can be improved. For example, a flash memory has a disadvantage that the number of times of rewriting is small compared with an EEPROM. In addition, in this embodiment, the memory cell array MA1 in which memory cells that are used in a flash memory are arranged can be handled as an EEPROM capable of writing data in units of bytes. Therefore, the number of times of rewriting is desirably as large as possible, as with the case of an EEPROM, and it is possible to meet such a demand by storing complementary data as each piece of bit data.

In addition, in this embodiment, the driver circuit DRC1 includes a first switch element in which an erasure voltage is supplied to its one end, and that supplies the erasure voltage to a first source line of the first memory cell group, and a second switch element in which an erasure voltage is supplied to its one end, and that supplies the erasure voltage to a second source line of the second memory cell group. Accordingly, an erasure voltage that is a voltage same as the erasure voltage that is supplied to the one end of the first switch element is supplied to the one end of the second switch element. For example, if A1 in FIG. 3 denotes the first memory cell group and A2 denotes the second memory cell group, the first switch element is the switch element SLSW0 and the second switch element is the switch element SLSW1. For example, the source line voltage VSL (=VPP) that is an erasure voltage is supplied to one end of the switch element SLSW0 that is the first switch element. Also, the switch element SLSW0 supplies the source line voltage VSL (=VPP), which is an erasure voltage, to the source line SL00 that is the first source line of the memory cell group A1. Specifically, the source line voltage VSL (=VPP) is supplied to the source line SL00 via the switch element SLDR00. In addition, the source line voltage VSL (=VPP) that is an erasure voltage is supplied to one end of the switch element SLSW1 that is the second switch element. The switch element SLSW1 then supplies the source line voltage VSL (=VPP), which is an erasure voltage, to the source line SL10 that is the second source line of the memory cell group A2. Specifically, the source line voltage VSL (=VPP) is supplied to the source line SL10 via the switch element SLDR10.

If the first and second switch elements such as the switch element SLSW0 and SLSW1 are provided in this manner, it is possible to supply an erasure voltage to a source line of a memory cell group connected to a bit line group corresponding to the byte unit, and perform an erase operation on this memory cell group. Accordingly, an erase operation in units of bytes can be performed on the memory cell groups.

In addition, in this embodiment, the driver circuit DRC1 includes a third switch element whose one end is connected to the other end of the first switch element and whose other end is connected to the first source line, and that is switched on when a first word line select signal is activated, and a fourth switch element whose one end is connected to the other end of the second switch element, and whose other end is connected to the second source line, and that is switched on when the first word line select signal is activated.

For example, as described above, if the first and second switch elements are respectively the switch element SLSW0 and SLSW1, the third switch element is the switch element SLDR00, and the fourth switch element is the switch element SLDR10. Accordingly, one end of the switch element SLDR00 that is the third switch element is connected to the other end of the switch element SLSW0 that is the first switch element, and the other end of the switch element SLDR00 is connected to the source line SL00 that is the first source line of the memory cell group A1. The switch element SLDR00 is then switched on when the word line select signal WLSEL0, which is a first word line select signal, is activated. Specifically, when the word line select signal WLSEL0 changes to H level that is an active level, the switch element SLDR00 is switched on, and the source line voltage VSL (=VPP) is supplied to the source line SL00 via the switch element SLDR00. In addition, one end of the switch element SLDR10 that is the fourth switch element is connected to the other end of the switch element SLSW1 that is the second switch element, and the other end of the switch element SLDR10 is connected to the source line SL10 that is the second source line of the memory cell group A2. The switch element SLDR10 is then switched on when the word line select signal WLSEL0 that is the first word line select signal is activated. Specifically, when the word line select signal WLSEL0 changes to H level, the switch element SLDR10 is switched on, and the source line voltage VSL (=VPP) is supplied to the source line SL10 via the switch element SLDR10.

As a result of the third and fourth switch elements such as the switch elements SLDR00 and SLDR10 being provided in this manner, the source line voltage VSL (=VPP) from the first or second switch element such as the switch element SLSW0 or SLSW1 can be supplied to the source line SL00 or SL10 of the memory cell group A1 or A2. Accordingly, an erase operation in units of bytes can be performed on the memory cell groups.

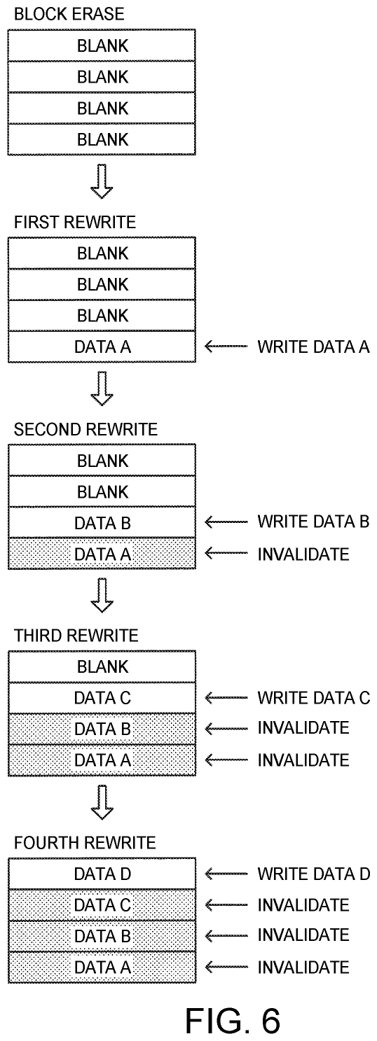

FIG. 6 is an explanatory diagram of the above-described EEPROM emulation technique. FIG. 6 shows a case where one block is constituted by first to fourth regions each having one byte, and is a region having four bytes in total. First of all, block erase is performed, and the first to fourth regions of the block are made blank. Then, in first rewriting, data A is written to the first region that is a blank region of the block. In second rewriting, the first regions is invalidated, and data B is written to the second region that is a blank region of the block. Similarly, in third rewriting and fourth rewriting, the second and third regions are invalidated, and data C and data D are written to the third and fourth regions that are blank regions of the block, respectively. When data is written to all of the first to fourth regions, block erase is performed and the first to fourth regions are made blank again. In FIG. 6, four pieces of data, namely the data A to the data D are written in the block, but, in actuality, rewriting is performed on the memory cells of the block only once. Accordingly, by performing EEPROM emulation in FIG. 6, the guaranteed number of times of rewriting can be increased fourfold.

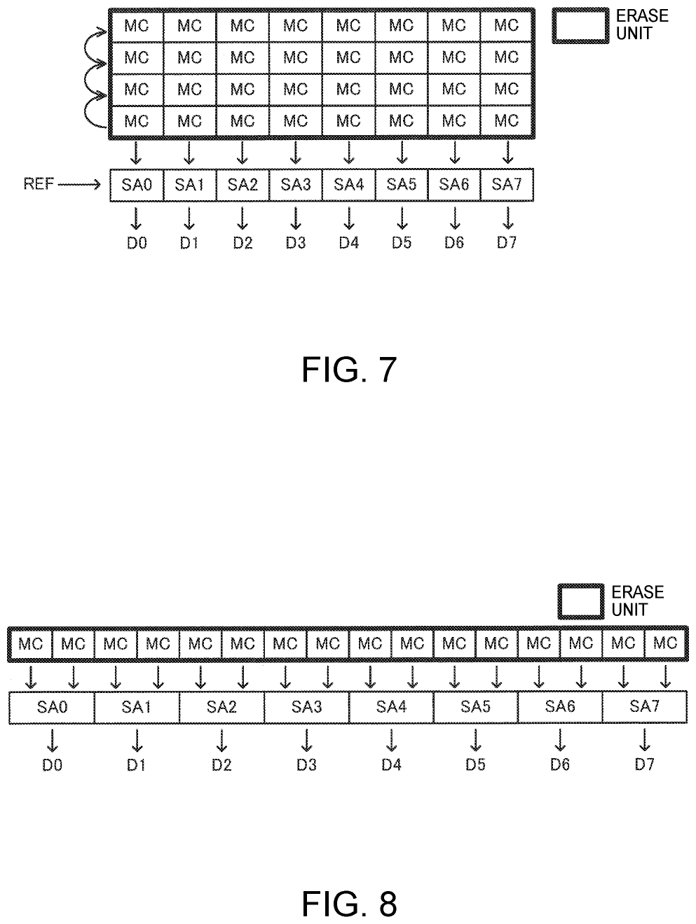

FIG. 7 is a diagram illustrating operations of EEPROM emulation. MC denote memory cell, and SA0 to SA7 denote sense amplifiers. A thick line portion indicates an erase unit. In EEPROM emulation, extra memory cells are provided, and every time data is rewritten, a data writing region is switched. By the sense amplifiers SA0 to SA7 comparing detection currents that flow in the memory cells MC with the reference current REF, data is read out.

However, if an attempt is made to guarantee the number of times of writing that is equivalent to that of an EEPROM through EEPROM emulation, it is necessary to increase the number of memory cells. In the example in FIG. 6, a four-times larger number of memory cells are required. For example, in order to guarantee the number of times of rewriting of 100000 when the number of times of rewriting of the flash memory is 1000, a 100-times larger number of memory cells are necessary, and the circuit area increases significantly.

In this regard, in this embodiment, the memory cell array MA1 in which memory cells that are used in a flash memory are arranged is divided, and the erase unit is set to the byte unit. In addition, the guaranteed number of times of rewriting is increased by adopting the complementary cell configuration instead of providing extra memory cells of the number corresponding to the number of times of rewriting as in EEPROM emulation. By increasing the guaranteed number of times of rewriting in this manner, the memory cell array MA1 can be used as an EEROM. It is also possible to prevent a large increase in the circuit area as in EEPROM emulation. For example, by adopting the complementary cell configuration, the number of memory cells is doubled, but there is the advantage that the effect of increasing the number of times of rewriting is more than twice, and that its efficiency is higher than that of a technique for providing extra cells.

In addition, in this embodiment, the erase unit is set to the byte unit, and thus troublesome processing for invalidating a data writing region and the like as in EEPROM emulation is not required. In addition, according to this embodiment, it is possible to reduce the number of memory cells connected to the same source line. For example, it is possible to reduce the number of memory cells respectively connected to the source lines SL00 to SL22 in FIG. 3, compared with a flash memory in which an erase operation is performed in units of blocks. Therefore, there are advantages that the influence of write disturbance is suppressed, and that it is easy to uniformize threshold values of memory cells when erasing and writing data.

FIG. 8 is an explanatory diagram of operations of the non-volatile memory device 10 of this embodiment. As shown in FIG. 8, in this embodiment, the complementary cell configuration is adopted, and 16 memory cells MC are used for storing one-byte data. During an erase operation, data in these 16 memory cells MC is erased, and an erase operation in units of bytes is performed. Since the complementary cell configuration is adopted, it is necessary to provide a two-times larger number of memory cells, but rewriting is always performed on the same memory cells. In addition, as shown in FIG. 8, a technique is adopted in which the sense amplifiers SA0 to SA7 each output one-bit data for two memory cells, and accordingly 8-bit data consisting of DO to D7 is read out.

In addition, in this embodiment, each of the memory cell groups of the memory cell array MA1 stores one-byte data, stores an error correction code of the data, and, using this error correction code, performs error correction of the stored data. With such a configuration, it is possible to further increase the guaranteed number of times of rewriting.

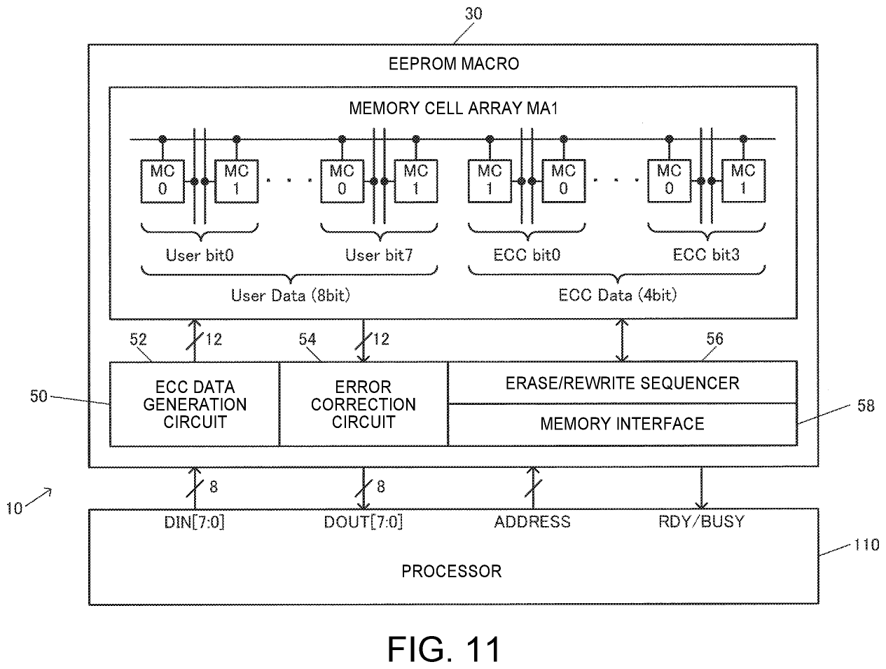

Specifically, as shown in FIG. 11 to be described later, the non-volatile memory device 10 includes an error correction circuit 54. For example, the EEPROM macro 30 includes a control circuit 50, and the error correction circuit 54 is provided in the control circuit 50. In addition, the first memory cell group of the memory cell array MA1 stores first data and a first error correction code of the first data. The second memory cell group of the memory cell array MA1 stores second data and a second error correction code of the second data. For example, the first memory cell group A1 in FIG. 3 stores first data of one byte and a first error correction code that is an error correction code for the first data. In addition, the second memory cell group A2 stores second data of one byte and a second error correction code that is an error correction code for the second data. The first error correction code is generated by an ECC data generation circuit 52 in FIG. 11 based on the first data, and is stored in the first memory cell group along with the first data. The second error correction code is generated by the ECC data generation circuit 52 based on the second data, and is stored in the second memory cell group along with the second data. Also, the error correction circuit 54 performs error correction on the first data read out from the first memory cell group, based on the first error correction code, and performs error correction on the second data read out from the second memory cell group, based on the second error correction code. For example, by adding a four-bit error correction code to one byte data, error correction can be performed on one-bit data.

Error correction is processing for detecting that an error value is stored in a memory cell, using an ECC, and correcting the error to a correct value. The ECC is a redundant code that is added for enabling automatic correction of an error of data. Examples of error correction processing include processing using a humming code, processing using a CRC (Cyclic Redundancy Check), and the like. The humming code is used in an error detection correction method in which redundant bits are added to information, and makes it possible to detect errors in two bits, and correct a one-bit error. The CRC is used in a method in which the remainder of division by a certain generator polynomial is used as redundant bits for inspection.

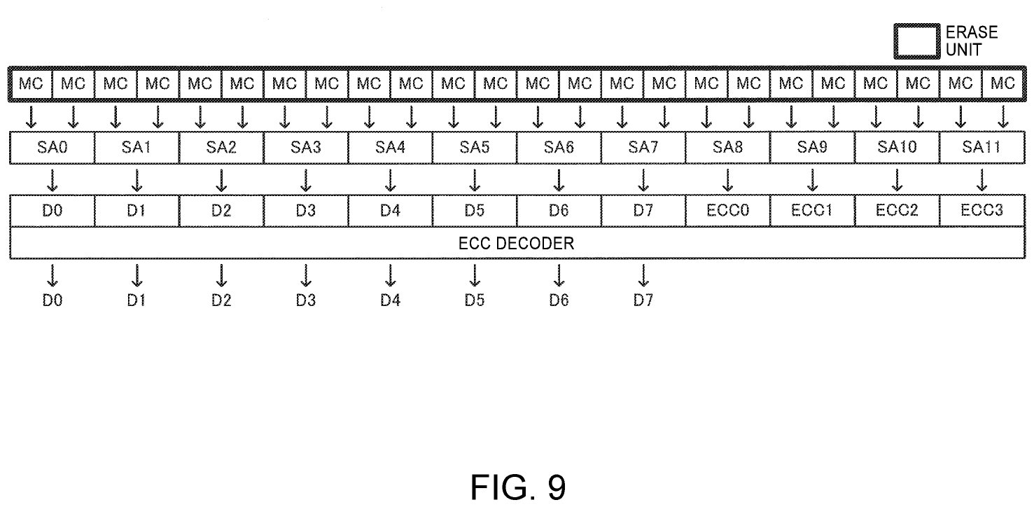

FIG. 9 is an explanatory diagram of a technique of this embodiment for adding ECC (Error Correcting Code). In this embodiment, information regarding ECC is added in correspondence with the rewriting unit. For example, in FIG. 9, 16 memory cells MC that have the complementary cell configuration store one-byte data, and eight memory cells MC that have the complementary cell configuration store ECC corresponding to four bits. Pieces of data DO to D7 corresponding to one byte are then read out from the 16 memory cells MC for storing data, using the sense amplifiers SA0 to SA7. Also, ECCs 0 to 3 that are the ECC corresponding to four bits are read out from the eight memory cells MC for storing ECC, using sense amplifiers SA8 to SA11. Error detection and error correction are then performed on DO to D7 using the ECCs 0 to 3. In general, ECC aim to reduce the error rate, but, in this embodiment, the number of times of rewriting is improved using ECC. For example, when performing one-bit error correction of eight-bit data, 4-bit ECC is required. Therefore, when adding ECC, the number of memory cells need to be increased to 1.5 times, but, if improvement in the number of times of rewriting is taken into consideration, effects more than compensating an increase in the circuit area are achieved.

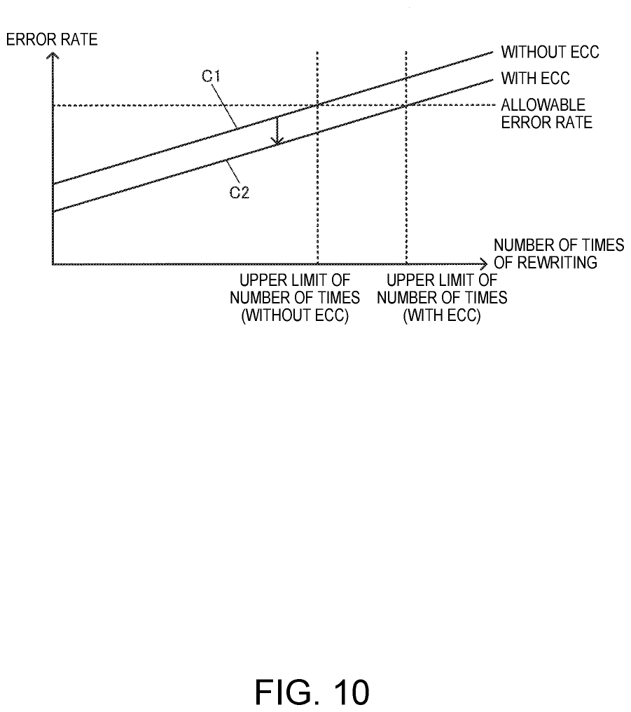

FIG. 10 is an explanatory diagram of an improvement in the number of times of rewriting by using ECC. C1 in FIG. 10 indicates an error rate when ECC is not used, and C2 indicates an error rate when ECC is used. The error rate can be reduced by using ECC. In addition, the intersection between the allowable error rate and each of the characteristic lines of C1 and C2 is used as an upper limit of the number of times of writing that is the allowable number of times of writing. As shown in FIG. 10, by using ECC, it is possible to increase the upper limit of the number of times of writing.

FIG. 11 shows an exemplary circuit configuration of the non-volatile memory device 10 when ECC is used. In FIG. 11, the control circuit 50 is provided in the EEPROM macro 30 that has the memory cell array MA1. The control circuit 50 is a logic circuit that performs control of the driver circuit DRC1 and the read/write circuit RWC1, and the like. The control circuit 50 includes the ECC data generation circuit 52 that generates ECC data, the error correction circuit 54 that performs error correction based on ECC, an erase/rewrite sequencer 56, and a memory interface 58.

In each of the memory cell groups of the memory cell array MA1, four-bit ECC data is added to one-byte data that is user data, and is stored. An erase operation and a rewrite operation in this memory cell array MA1 are controlled by an erase/rewrite sequencer. In addition, the memory interface 58 performs interface processing between the EEPROM macro 30 and a processor 110. The processor 110 is a CPU, for example, and specifically, a CPU core of the microcomputer 100 in FIG. 16.

The processor 110 designates a writing address, and outputs, to the EEPROM macro 30, one-byte data DIN[7:0] that is to be written to this address. The ECC data generation circuit 52 generates ECC data based on the data DIN[7:0]. The data DIN[7:0] and the ECC data are then written to a memory cell group corresponding to the address instructed by the processor 110. In addition, the processor 110 designates a readout address, and reads out data from the EEPROM macro 30. In this case, user data and the ECC data are read out from the memory cell group of the memory cell array MA1 designated by this address. The error correction circuit 54 performs error correction of the user data based on the ECC that has been read out. Accordingly, one-byte data DOUT[7:0] after error correction is output to the processor 110.

In FIG. 11, by adopting the complementary cell configuration, and using ECC, the number of times of rewriting is increased, and the data retention characteristics is improved. In addition, it is also possible to improve the reliability by using ECC. In addition, in FIG. 11, the EEPROM macro 30 is provided with the memory interface 58 that allows the EEPROM macro 30 to operate like an EEPROM when viewed from the processor 110 that is a CPU. For example, when writing data, it suffices for the processor 110 to designate a writing address, and output the data DIN[7: 0] that is to be written. For example, the EEPROM macro 30 informs the processor 110 that rewriting or the like has ended, using a signal RDY/BUSY for notifying a ready state or a busy state. In addition, when reading out data, the processor 110 can designate a readout address and thereby read out the corresponding one byte data DOUT[7: 0]. Therefore, the processor 110 does not need to be conscious of an erase operation and the like required for a flash memory, and, for example, can rewrite data by issuing a write command, or the like. Therefore, the processor 110 can handle the EEPROM macro 30 like a real EEPROM, and it is possible to realize the non-volatile memory device 10 in which an EEPROM and a flash memory are provided together and can be used.

FIG. 12 shows an example of the overall circuit configuration of the non-volatile memory device 10 of this embodiment. In FIG. 10, the non-volatile memory device 10 includes the EEPROM macro 30, the flash memory macro 40, a logic power supply circuit 60, and a voltage boosting circuit 62.

The EEPROM macro 30 includes the memory cell array MA1, the driver circuit DRC1, the read/write circuit RWC1, and the control circuit 50. The flash memory macro 40 includes the memory cell array MA2, the driver circuit DRC2, the read/write circuit RWC2, and a control circuit 51. The EEPROM macro 30 and the flash memory macro 40 are macro blocks of an integrated circuit device that is the non-volatile memory device 10. A macro block is also called a hardware macro, and is a block in which circuit blocks that constitute the macro block are laid out and integrated on an IC (integrated circuit device). The logic power supply circuit 60 generates a logic power supply voltage, and supplies the logic power supply voltage to the EEPROM macro 30 and the flash memory macro 40. The voltage boosting circuit 62 performs a boosting operation such as charge pumping, generates a high voltage that is a boosted voltage, and supplies the high voltage to the EEPROM macro 30 and the flash memory macro 40.

For example, in the above-described EEPROM emulation, it is necessary to load and store a program for executing EEPROM emulation to a RAM, and there is a problem in that the storage capacity of the RAM that is used by the user decreases. In this regard, in this embodiment, a macro block for realizing an EEPROM in a pseudo manner and a macro block for a flash memory, namely the EEPROM macro 30 and the flash memory macro 40, are provided as hardware. Therefore, the above-mentioned problem of decrease in the storage capacity of the RAM that is used by the user can be prevented from occurring. In addition, the non-volatile memory device 10 can be handled as if a real EEPROM and flash memory are provided together, and the convenience can be improved. In addition, the EEPROM macro 30 and the flash memory macro 40 can be used as hardware separately at the same time. Therefore, for example, there is the advantage that it is possible to perform simultaneous processing in which the processor 110 performs processing according to a program stored in the flash memory macro 40 and writes the processing result to the EEPROM macro 30 at the same time.

In addition, in this embodiment, as shown in FIG. 12, the non-volatile memory device 10 includes the voltage boosting circuit 62 that performs a boosting operation, and generates an erasing and rewriting voltage. Also, the voltage boosting circuit 62 supplies the erasing and rewriting voltage to the driver circuit DRC1 and the driver circuit DRC2. Specifically, the voltage boosting circuit 62 performs a boosting operation such as charge pumping based on an external power supply, and generates a boosted voltage that is a high voltage. The voltage boosting circuit 62 then supplies the generated boosted voltage as an erasing and rewriting voltage to the EEPROM macro 30 and the flash memory macro 40. The driver circuit DRC1 of the EEPROM macro 30 and the driver circuit DRC2 of the flash memory macro 40 perform an erase operation and a write operation based on the boosted voltage from the voltage boosting circuit 62. The erasing and rewriting voltage that is a boosted voltage is the source line voltage VSL or the word line voltage VWL in FIGS. 3, 4, and 5, for example, and is a high voltage of 7.5 V or the like higher than the logic power supply voltage, for example.

In this embodiment, memory cells having the same structure are arranged in the memory cell array MA1 and the memory cell array MA2. Therefore, the EEPROM macro 30 and the flash memory macro 40 can use the same power supply voltage. Specifically, the erasing and rewriting voltage from the voltage boosting circuit 62 can be shared by the EEPROM macro 30 and the flash memory macro 40, and there is the advantage that a power supply dedicated for each of the EEPROM macro 30 and the flash memory macro 40 is not necessary. Accordingly, for example, it is not required to provide two voltage boosting circuits 62, and it is possible to reduce the scale of the circuit area, and the like.

In addition, as shown in FIG. 12, the non-volatile memory device 10 of this embodiment includes a verification circuit VRC1 that performs a verifying operation on a plurality of memory cells of the memory cell array MA1, and a verification circuit VRC2 that performs a verifying operation on a plurality of memory cells of the memory cell array MA2. The verification circuit VRC1 and the verification circuit VRC2 are respectively a first verification circuit and a second verification circuit, and are realized by verification sequencers and the like. In a verifying operation, for example, in order to check whether or not data written in memory cells is normal, the data written in the memory cells is read out, and is compared with writing data. Specifically, every time a write operation or an erase operation is performed, the verification circuit VRC1 and the verification circuit VRC2 perform a verifying operation, check the threshold values of the memory cells, and when a necessary threshold value level is reached, stop the write operation or the erase operation, and thereby perform control so as to prevent excessive charge injection. With such a configuration, it is possible to appropriately control the threshold values of the memory cells, deterioration of the threshold values of the memory cells is suppressed, and it is possible to increase the number of times of rewriting.

In addition, such a verifying operation is normally performed in a flash memory, but not performed in an EEPROM. In this regard, in this embodiment, as shown in FIG. 12, the verification circuit VRC1 and the verification circuit VRC2 are provided in the EEPROM macro 30 and the flash memory macro 40, respectively. The verification circuit VRC2 performs a verifying operation on the memory cell array MA2 that is used as a flash memory. On the other hand, the verification circuit VRC1 performs a verifying operation on the memory cell array MA1 that is used as a pseudo EEPROM as well. Accordingly, normally, a verifying operation is not performed on an EEPROM, but, in this embodiment, a verifying operation is performed on the memory cell array MA1 that is used as a pseudo EEPROM. With such a configuration, deterioration of the threshold values of the memory cells is suppressed, and it is possible to increase the number of times of rewriting, and to bring the guaranteed number of times of writing close to the guaranteed number of times of writing of a normal EEPROM.

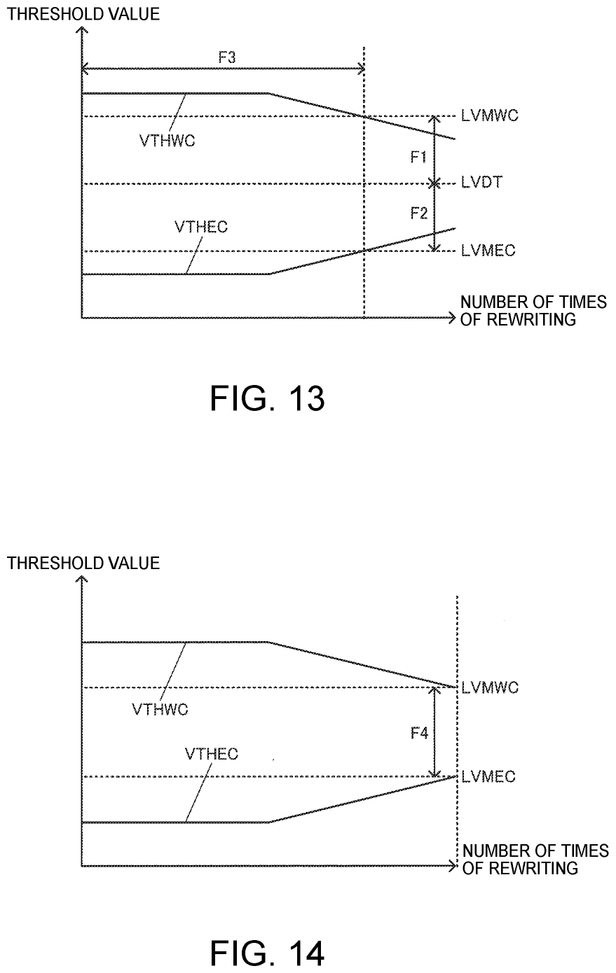

Next, the effects of this embodiment will be described with reference to FIGS. 13 and 14. FIGS. 13 and 14 are diagrams showing change in a threshold value as data of a memory cell is repeatedly rewritten. VTHWC denotes a threshold value of a memory cell in a written state, and the threshold value VTHWC falls as data is repeatedly rewritten. VTHEC denotes a threshold value of a memory cell in an erased state, and the threshold value VTHEC rises as data is repeatedly rewritten. Here, the memory cell in a written state is a memory cell that stores “0”, and the memory cell in an erased state is a memory cell that stores “1”.

Readout determination of data in a memory cell is performed using a readout determination level LVDT. In addition, the memory cell in a written state and the memory cell in an erased state have threshold value levels LVMWC and LVMEC that are margin levels required for distinguishably reading out data. For example, when the threshold value VTHWC of the memory cell in a written state falls below the threshold value level LVMWC, readout determination cannot be performed, and rewriting after this is not possible. In addition, when the threshold value VTHEC of the memory cell in an erased state exceeds the threshold value level LVMEC, readout determination cannot be performed, and rewriting after this is not possible. Accordingly, rewriting in the memory cell in a written state is possible until the threshold value VTHWC of this memory cell reaches the threshold value level LVMWC that includes a margin denoted by F1 with respect to the readout determination level LVDT. Rewriting in the memory cell in an erased state is possible until the threshold value VTHEC of this memory cell reaches the threshold value level LVMEC that includes a margin denoted by F2 with respect to the readout determination level LVDT. Therefore, in FIG. 13, rewriting in a memory cell is possible within the range of a number of times F3, and the number of times of writing that exceeds the range of the number of times F3 is not possible.

For example, by using the above-described EEPROM emulation technique while making a switch to extra cells, the rewriting frequency in each memory cell is reduced, and the EEPROM emulation technique is used within a range where the threshold value of the memory cell does not deteriorate. On the other hand, in this embodiment, the deterioration characteristics of the threshold value of each individual memory cell does not change, but the complementary cell configuration is adopted, and thus, as shown in FIG. 14, data can be distinguishably read out in a state where the threshold value of the memory cell further deteriorates. Accordingly, in a configuration in which complementary cells are not adopted, readout determination is performed by comparing a detection current that flows in a memory cell with a reference current. Thus, data can be rewritten only within the range of the number of times indicated by F3 in FIG. 13. On the other hand, in the complementary cell configuration, a detection current that flows in a memory cell in a written state is compared with a detection current that flows in a memory cell in an erased state. In other words, a detection current that flows in a memory cell that stores “0” is compared with a detection current that flows in a memory cell that stores “1”. Therefore, as indicated by F4 in FIG. 14, data can be distinguishably read out even with a small threshold value difference, and accordingly, compared with FIG. 13, it is possible to increase the guaranteed number of times of writing. Accordingly, although the deterioration characteristics of the threshold value of each memory cell is the same as a conventional example, a larger number of times of rewriting is allowed.

In addition, in this embodiment, a plurality of memory cells of the memory cell array MA1 and a plurality of the memory cells of the memory cell array MA2 are memory cells of the same structure, and this structure of the memory cells is a MONOS structure, for example.

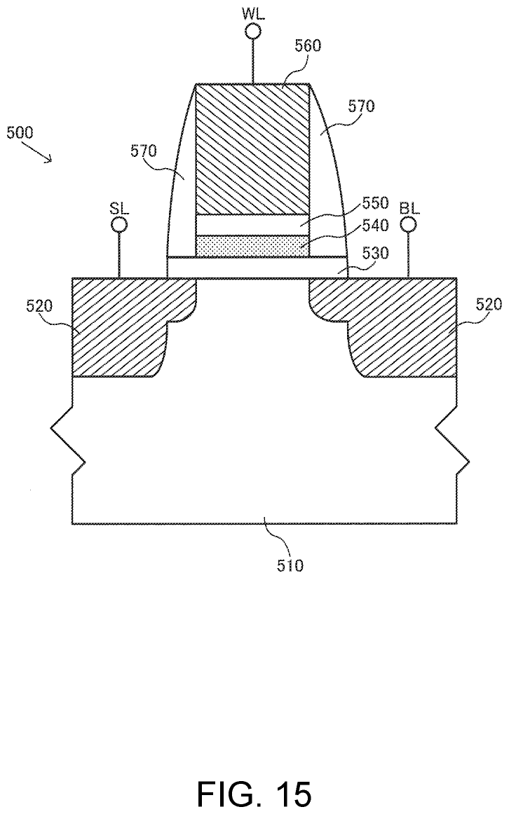

FIG. 15 shows an example of a memory cell 500 having the MONOS structure. The MONOS structure is also called a SONOS (Silicon Oxide Nitride Oxide Silicon) structure. The memory cell 500 in FIG. 15 has a semiconductor substrate 510 that is a semiconductor layer, source/drain regions 520, a first gate insulation layer 530, a gate charge accumulation layer 540, a second gate insulation layer 550, a gate conductive layer 560, and an insulation layer 570. One of the source/drain regions 520 is connected to the source line SL, and the other is connected to the bit line BL. The gate conductive layer 560 is connected to the word line WL. The gate charge accumulation layer 540 is, for example, formed of a silicon nitride layer such as a Si₃N₄ layer, and the gate conductive layer 560 is formed of a polysilicon layer, for example. In addition, the first gate insulation layer 530, the second gate insulation layer 550, and the insulation layer 570 are formed of a silicon oxide layer (SiO₂ layer), for example. Accordingly, the MONOS structure is realized. In the memory cell 500 of the MONOS structure, some of electrons that travel through a channel turn into hot electrons, and are injected into and captured in the gate charge accumulation layer 540 over the barrier of the first gate insulation layer 530, and thereby data is written. Accordingly, the threshold value of the memory cell 500 changes according to whether not electric charges are trapped in the gate charge accumulation layer 540, and whether the stored data is 0 or 1 is determined based on this change.

Note that the memory cells of the memory cell arrays MA1 and MA2 may be memory cells of a floating gate structure. In a memory cell of the floating gate structure, a source region and a drain region are formed on the surface of a semiconductor substrate, and a floating gate is formed on the semiconductor substrate via a tunnel oxide film. In addition, a control gate is formed on the floating gate via an insulation film. Note that if memory cells of the same structure such as the floating gate structure are used, the memory cells that are arranged in the memory cell array MA1 may be high voltage memory cell compared with memory cells that are arranged in the memory cell array MA2. In this case, as a step for forming memory cells of the memory cell array MA1, a step for forming a high voltage device may be added. If high voltage memory cells are arranged in the memory cell array MA1 in this manner, a higher voltage can be applied as an erasing and rewriting voltage, and it is possible to further increase the guaranteed number of times of rewriting in the memory cell array MA1.

### 3. Microcomputer and Electronic Device

FIG. 16 shows a configuration example of the microcomputer 100 that includes the non-volatile memory device 10 of this embodiment. The microcomputer 100 of this embodiment includes the non-volatile memory device 10 of this embodiment described with reference to FIGS. 1 to 4, for example, and the processor 110 that performs data processing. The microcomputer 100 can also include the RAM 120, an interface circuit 122, a power supply circuit 124, a reset circuit 126, a timer 128, and the like. The processor 110 is a CPU core, and executes various types of data processing. The non-volatile memory device 10 is a memory device that can be used as an EEPROM and a flash memory. For example, a firmware program and the like are stored in the memory cell array MA2 of the non-volatile memory device 10, and user data and the like are stored in the memory cell array MA1 of the non-volatile memory device 10. In addition, the processor 110 executes various types of processing based on programs and data stored in the non-volatile memory device 10. The RAM 120 stores data that is used by the processor 110 and the like, and functions as a work memory of the processor 110, for example. The interface circuit 122 is a circuit that realizes an interface such as an I2C (Inter Integrated Circuit), an SPI (Serial Peripheral Interface), or a UART (Universal Asynchronous Receiver/Transmitter). The power supply circuit 124 is a circuit that generates various power supply voltages used by the microcomputer 100 and the like. The reset circuit 126 is a circuit that performs processing such as power-on reset. The timer 128 is a circuit that realizes an 8-bit timer, a 16-bit timer, a counting timer, a watchdog timer, and the like.

According to the microcomputer 100 provided with the non-volatile memory device 10 of this embodiment, the processor 110 can realize various types of processing using the non-volatile memory device 10 that functions as EEPROM and a flash memory.

FIG. 17 shows a configuration example of an electronic device 300 that includes the non-volatile memory device 10 of this embodiment. The electronic device 300 can include the microcomputer 100 that has the non-volatile memory device 10 of this embodiment, a display unit 310, a memory 320, an operation interface 330, and a communication interface 340. Note that, in FIG. 17, the non-volatile memory device 10 of this embodiment is provided in the microcomputer 100, but the non-volatile memory device 10 may be provided outside of the microcomputer 100. For example, the non-volatile memory device 10 may be used as the memory 320. Specific examples of the electronic device 300 include a panel apparatus such as a meter panel, an in-vehicle apparatus such as a car navigation system, a sensor apparatus that has a sensor such as a gyro sensor or an acceleration sensor, a projector, a head mounted display, a printing apparatus, a mobile information terminal, a portable game machine, and a robot, or various electronic devices such as an information processing apparatus.

The microcomputer 100 that is a processing apparatus performs processing for controlling the electronic device 300, various types of signal processing, and the like. The display unit 310 can be realized by a liquid crystal panel, an organic EL panel, or the like. The display unit 310 may be a touch panel. The memory 320 stores data from the operation interface 330 and the communication interface 340, for example, or functions as a work memory of the microcomputer 100. The memory 320 can be realized by a semiconductor memory such as a RAM or a ROM, or a magnetic memory device such as a hard disk drive, for example. The operation interface 330 is a user interface that accepts various operations from the user. For example, the operation interface 330 can be realized by a button, a mouse, and a keyboard, or a touch panel and the like. The communication interface 340 is an interface for performing communication of image data and control data. Communication processing of the communication interface 340 may be wired communication processing, or may be wireless communication processing.

As described above, the non-volatile memory device of this embodiment includes a first memory cell array in which a plurality of non-volatile memory cells capable of electrically writing and erasing data are arranged, a first driver circuit that drives a word line and a source line of the first memory cell array, and a first read/write circuit that is connected to bit lines of the first memory cell array, and writes/reads out data to/from the first memory cell array. The non-volatile memory device also includes a second memory cell array in which a plurality of non-volatile memory cells capable of electrically writing and erasing data are arranged, a second driver circuit that drives a word line and a source line of the second memory cell array, and a second read/write circuit that is connected to bit lines of the second memory cell array, and writes/reads out data to/from the second memory cell array. A plurality of non-volatile memory cells having the same structure as the plurality of memory cells of the first memory cell array are arranged in the second memory cell array. In addition, the first driver circuit performs an erase operation in units of bytes on the first memory cell array, and the second driver circuit performs an erase operation in units of blocks, a block being larger than a byte, on the second memory cell array.

According to this embodiment, the first and second memory cell arrays in which non-volatile memory cells having the same memory structure are arranged are provided. Also, the first driver circuit and the first read/write circuit are provided in correspondence with the first memory cell array, and the second driver circuit and the second read/write circuit are provided in correspondence with the second memory cell array. The first driver circuit performs an erase operation in units of bytes on the first memory cell array while the second driver circuit performs an erase operation in units of blocks on the second memory cell array. With such a configuration, the first memory cell array can be used as an EEPROM, and the second memory cell array can be used as a flash memory. In addition, since the memory cells of the same structure are used as memory cells of the first and second memory cells array, it is possible to realize reduction in the circuit area and the cost. Therefore, it is possible to realize provision of a non-volatile memory device and the like that can cope with both the usages of an EEPROM and a flash memory while realizing reduction in the circuit area.

In addition, in this embodiment, a configuration may be adopted in which, during the erase operation in units of bytes, the first driver circuit supplies an erasure voltage to a source line of a memory cell group connected to a bit line group corresponding to the byte unit, and, during the erase operation in units of blocks, the second driver circuit supplies the erasure voltage to a source line of a memory cell group connected to a bit line group corresponding to the block unit.

With such a configuration, an erase operation in units of bytes can be performed on the first memory cell array, and a batch erase operation in units of blocks can be performed on the second memory cell array.

In addition, in this embodiment, the first memory cell array may include a first memory cell group that stores one-byte first data and a second memory cell group that stores one-byte second data. The first driver circuit may perform the erase operation in units of bytes on the first memory cell group and the first read/write circuit may write the first data to the first memory cell group after the erase operation, and the first driver circuit may perform the erase operation in units of bytes on the second memory cell group and the first read/write circuit may write the second data to the second memory cell group after the erase operation.

With such a configuration, after the erase operation in units of bytes on the first memory cell group, one-byte first data can be written to the first memory cell group. In addition, after the erase operation in units of bytes on the second memory cell group, one-byte second data can be written to the second memory cell group.

In addition, in this embodiment, the first memory cell group may store complementary data that is mutually complementary data as each bit data of the first data, and the second memory cell group may store complementary data that is mutually complementary data as each bit data of the second data.

By storing complementary data as each bit data, it is possible increase the number of times of rewriting, and improve the endurance characteristics.

In addition, this embodiment includes an error correction circuit, and the first memory cell group may store the first data and a first error correction code of the first data, and the second memory cell group may store the second data and a second error correction code of the second data. Also, the error correction circuit may perform error correction on the first data read out from the first memory cell group, based on the first error correction code, and perform error correction on the second data read out from the second memory cell group, based on the second error correction code.

With such a configuration, if an error value is stored in a memory cell of the first memory cell array, the error can be corrected, and it is possible to improve number of times of rewriting in the first memory cell array.

In addition, in this embodiment, the first driver circuit may include a first switch element in which an erasure voltage is supplied to its one end, and that supplies the erasure voltage to a first source line of the first memory cell group, and a second switch element in which an erasure voltage is supplied to its one end, and that supplies the erasure voltage to a second source line of the second memory cell group.

As a result of providing such first and second switch elements, it is possible to supply an erasure voltage to the first or second source line of the first or second memory cell group connected to a bit line group corresponding to the byte unit, and perform an erase operation on the first or second memory cell group, and an erase operation in units of bytes can be performed.

In addition, in this embodiment, the first driver circuit may include a third switch element whose one end is connected to the other end of the first switch element, and whose other end is connected to the first source line, and that is switched on when a first word line select signal is activated, and a fourth switch element whose one end is connected to the other end of the second switch element, and whose other end is connected to the second source line, and that is switched on when the first word line select signal is activated.

As a result of providing such third and fourth switch elements, the erasure voltage from the first or second switch element can be supplied to the first or second source line of the first or second memory cell group via the third or fourth switch element that has been switched on by the first word line select signal, and an erase operation in units of bytes is possible.

In addition, in this embodiment, a voltage boosting circuit that performs a boosting operation, and generates an erasing and rewriting voltage may be included, and the voltage boosting circuit may supply the erasing and rewriting voltage to the first driver circuit and the second driver circuit.

With such a configuration, the voltage boosting circuit that generates an erasing and rewriting voltage used in the first and second driver circuits can be shared by the first and second memory cells arrays, and it is possible to reduce the scale of the circuit, and the like.

In addition, in this embodiment, a first verification circuit that performs a verifying operation of the plurality of memory cells of the first memory cell array and a second verification circuit that performs a verifying operation of the plurality of memory cells of the second memory cell array may be included.

With such a configuration, deterioration of a threshold value of a memory cell is suppressed, the number of times of rewriting can be increased, and, for example, it is possible to bring the guaranteed number of times of writing in the first memory cell array close to the guaranteed number of times of writing in a normal EEPROM.

In addition, in this embodiment, the plurality of memory cells of the first memory cell array and the plurality of memory cells of the second memory cell array may be memory cells of a MONOS structure or a floating gate structure.

By using such memory cells of the MONOS structure or the like, it is possible to reduce the scale of the circuit area of the non-volatile memory device.

In addition, this embodiment pertains to a microcomputer that includes the above-described non-volatile memory device and a processor that performs data processing. In addition, this embodiment pertains to an electronic device that includes the above-described non-volatile memory device.

Note that, this embodiment has been described above in detail, but a person skilled in the art can easily understand that many modification can be made without substantially departing from new matters and effects of the present disclosure. Therefore, such modified examples are all included in the scope of the present disclosure. For example, in the specification or drawings, a term mentioned along with another broader term or another synonymous term at least once can be replaced with the other term, wherever in the specification or drawings the term is. In addition, all the combinations of this embodiment and modified examples are also included in the scope of the present disclosure. In addition, the configurations and operations of the non-volatile memory device, the microcomputer, the electronic device, and the like are not limited to those described in this embodiment, and various modifications can be made.

What is claimed is:

1. A non-volatile memory device comprising:
a first memory cell array in which a plurality of non-volatile memory cells capable of electrically writing and erasing data are arranged;
a first driver circuit that drives a word line and a source line of the first memory cell array;
a first read/write circuit that is connected to bit lines of the first memory cell array, and writes/reads out data to/from the first memory cell array;
a second memory cell array in which a plurality of non-volatile memory cells capable of electrically writing and erasing data and having the same structure as the plurality of memory cells of the first memory cell array are arranged;
a second driver circuit that drives a word line and a source line of the second memory cell array; and
a second read/write circuit that is connected to bit lines of the second memory cell array, and writes/reads out data to/from the second memory cell array,
wherein the first driver circuit performs an erase operation in units of bytes on the first memory cell array, and
the second driver circuit performs an erase operation in units of blocks, a block being larger than a byte, on the second memory cell array.

2. The non-volatile memory device according to claim 1,
wherein, during the erase operation in units of bytes, the first driver circuit supplies an erasure voltage to a source line of a memory cell group connected to a bit line group corresponding to the byte unit, and
during the erase operation in units of blocks, the second driver circuit supplies the erasure voltage to a source line of a memory cell group connected to a bit line group corresponding to the block unit.

3. The non-volatile memory device according to claim 1,
wherein the first memory cell array includes:
a first memory cell group that stores one-byte first data, and
a second memory cell group that stores one-byte second data, and
the first driver circuit performs the erase operation in units of bytes on the first memory cell group and the first read/write circuit writes the first data to the first memory cell group after the erase operation, and
the first driver circuit performs the erase operation in units of bytes on the second memory cell group and the first read/write circuit writes the second data to the second memory cell group after the erase operation.

4. The non-volatile memory device according to claim 3,
wherein the first memory cell group stores complementary data that is mutually complementary data as each bit data of the first data, and
the second memory cell group stores complementary data that is mutually complementary data as each bit data of the second data.

5. The non-volatile memory device according to claim 3, further comprising:
an error correction circuit,
wherein the first memory cell group stores the first data and a first error correction code of the first data,
the second memory cell group stores the second data and a second error correction code of the second data, and
the error correction circuit performs error correction on the first data read out from the first memory cell group, based on the first error correction code, and performs error correction on the second data read out from the second memory cell group, based on the second error correction code.

6. The non-volatile memory device according to claim 3,
wherein the first driver circuit includes:
a first switch element in which an erasure voltage is supplied to its one end, and that supplies the erasure voltage to a first source line of the first memory cell group, and
a second switch element in which an erasure voltage is supplied to its one end, and that supplies the erasure voltage to a second source line of the second memory cell group.

7. The non-volatile memory device according to claim 6,
wherein the first driver circuit includes:
a third switch element whose one end is connected to the other end of the first switch element, and whose other end is connected to the first source line, and that is switched on when a first word line select signal is activated, and
a fourth switch element whose one end is connected to the other end of the second switch element, and whose other end is connected to the second source line, and that is switched on when the first word line select signal is activated.

8. The non-volatile memory device according to claim 1, further comprising:
a voltage boosting circuit that performs a boosting operation, and generates an erasing and rewriting voltage,
wherein the voltage boosting circuit supplies the erasing and rewriting voltage to the first driver circuit and the second driver circuit.

9. The non-volatile memory device according to claim 1, further comprising:
a first verification circuit that performs a verifying operation of the plurality of memory cells of the first memory cell array, and
a second verification circuit that performs a verifying operation of the plurality of memory cells of the second memory cell array.

10. The non-volatile memory device according to claim 1,
wherein the plurality of memory cells of the first memory cell array and the plurality of memory cells of the second memory cell array are memory cells of a MONOS structure or a floating gate structure.

11. A microcomputer comprising:
the non-volatile memory device according to claim 1, and
a processor that performs data processing.

12. An electronic device comprising:
the non-volatile memory device according to claim 1.
